(19) United States
(12) Patent Application Publication
(10) Pub. No.: US 2026/0173690 A1
(43) Pub. Date: Jun. 18, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Yang YANG, Hefei (CN); Lifang WANG, Hefei (CN); Chunyang LIU, Hefei (CN)

(73) Assignees: Hefei Visionox Technology Co., Ltd., Hefei (CN); Visionox Technology Inc., Kunshan (CN)

(21) Appl. No.: 19/426,164

(22) Filed: Dec. 19, 2025

Related U.S. Application Data
(63) Continuation of application No. PCT/CN2025/130981, filed on Oct. 29, 2025.

(30) Foreign Application Priority Data
Dec. 13, 2024 (CN) 202411846552.4

(51) Int. Cl. H10K 59/131; H10K 59/122

(52) U.S. Cl. CPC H10K 59/131; H10K 59/122

(57) ABSTRACT

Disclosed are a display panel and a display device. In the display panel, an isolation structure is electrically connected to a bonding region through a first power line. The isolation structure includes a connection region. An orthographic projection of the connection region on a substrate is located within an orthographic projection of the first power line on the substrate. The connection region includes a plurality of first connection holes. The isolation structure is electrically connected to a second end of the first power line through the plurality of first connection holes. A total area of the plurality of first connection holes is greater than a total area of an overlapping region between the first power line and the bonding region, thereby significantly reducing the risk of screen burn-in.

### CROSS-REFERENCE TO RELATED APPLICATIONS

This application is a continuation of International Application No. PCT/CN2025/130981, filed on Oct. 29, 2025, which claims priority to Chinese Patent Application No. 2024118465524, filed on Dec. 13, 2024. The disclosures of the aforementioned applications are hereby incorporated by reference in their entireties.

### FIELD

The present disclosure generally relates to the field of display technologies, and in particular, to a display panel and a display device.

### BACKGROUND

Organic Light Emitting Diodes (OLEDs) and flat-panel displays based on technologies such as Light Emitting Diodes (LEDs) and the like have become mainstream owing to advantages like high image quality, low power consumption, slim profile, and broad applicability, and are now widely used in mobile phones, televisions, notebook computers, desktop computers, and various other consumer electronic products. In a traditional preparation process of display panels, light-emitting pixels are typically patterned using a Fine Metal Mask (FMM). The FMM technology is mature and has rich experience in mass production. However, this technology also has problems such as limited precision and high cost. Technology of no fine metal mask eliminates limitations of traditional OLED processes on display screen size, resolution, and other screen performance, and has advantages of high performance, full-size scalability, and rapid turnaround. Patents of CN118251982A, CN116648095A, CN117062489A, CN118742138A, CN118678783A, CN118660598A, CN118675450A, CN118824188A, and CN118781966A contain relevant content on the technology of no fine metal mask, for reference.

However, performance of current OLED display products still needs to be improved.

### SUMMARY

To overcome shortcomings in the prior art mentioned above, the present disclosure aims to provide a display panel. The display panel includes a display region and a bonding region located beside the display region. The display panel includes a substrate; a wiring layer located on a side of the substrate, where the wiring layer includes at least one first power line, and a first end of the first power line is connected to the bonding region; and an isolation structure, located on a side, facing away from the substrate, of the wiring layer, where at least part of the isolation structure is located in the display region, and electrically connected to the bonding region through the at least one first power line; where the isolation structure includes at least one connection region, an orthographic projection of the connection region on the substrate is located within an orthographic projection of the first power line on the substrate, the at least one connection region includes a plurality of first connection holes, the isolation structure is electrically connected to a second end of the first power line through the plurality of first connection hole, and a total area of the plurality of first connection holes is greater than a total area of an overlapping region between the first power line and the bonding region.

The other purpose of the present disclosure is to provide a display panel. The display panel includes a display region and a bonding region located beside the display region. The display panel includes a substrate; a wiring layer located on a side of the substrate, where the wiring layer includes at least a first power line, and a first end of the first power line overlaps with the bonding region; and an isolation structure, located on a side, facing away from the substrate, of the wiring layer, where at least part of the isolation structure is located in the display region, and electrically connected to the bonding region through the at least one of the first power lines; and where the isolation structure includes at least one connection region, an orthographic projection of the connection region on the substrate is located within an orthographic projection of the at least one first power line on the substrate, the isolation structure is connected to the at least one first power line in the at least one connection region, a total area of the at least one connection region is greater than or equal to 0.1% of an area of the display region.

The other purpose of the present disclosure is to provide a display device. The display device includes the display panel provided by the present disclosure.

The present disclosure has the following beneficial effects.

The present disclosure provides a display panel and a display device. By setting a total area of an overlapping region of via holes between an isolation structure and a first power line to be greater than a total area of an overlapping region between the first power line and a bonding region, a connection area between the isolation structure and the first power line is increased, thereby reducing a risk of screen burn-in at a connection contact between the isolation structure and the first power line due to high current density.

### BRIEF DESCRIPTION OF THE DRAWINGS

FIG. 1 is a schematic diagram of a connection between an isolation structure and a first power supply according to an embodiment of the present disclosure.

FIG. 2 is a cross-sectional view of a display panel according to the embodiment of the present disclosure.

FIG. 3 is another schematic diagram of a connection between an isolation structure and a first power supply according to an embodiment of the present disclosure.

FIG. 4 is still another schematic diagram of a connection between an isolation structure and a first power supply according to an embodiment of the present disclosure.

FIG. 5 is yet still another schematic diagram of a connection between an isolation structure and a first power supply according to an embodiment of the present disclosure.

FIG. 6 is yet still another schematic diagram of a connection between an isolation structure and a first power supply according to an embodiment of the present disclosure.

FIG. 7a is yet still another schematic diagram of a connection between an isolation structure and a first power supply according to an embodiment of the present disclosure.

FIG. 7b is yet still another schematic diagram of a connection between an isolation structure and a first power supply according to an embodiment of the present disclosure.

FIG. 8a is yet still another schematic diagram of a connection between an isolation structure and a first power supply according to an embodiment of the present disclosure.

FIG. 8b is yet still another schematic diagram of a connection between an isolation structure and a first power supply according to an embodiment of the present disclosure.

FIG. 9 s a schematic diagram of an isolation opening and a first connection hole according to an embodiment of the present disclosure.

FIG. 10a is yet still another schematic diagram of a connection between an isolation structure and a first power supply according to an embodiment of the present disclosure.

FIG. 10b is yet still another schematic diagram of a connection between an isolation structure and a first power supply according to an embodiment of the present disclosure.

FIG. 11 is another cross-sectional view of a display panel according to an embodiment of the present disclosure.

FIG. 12 is yet still another schematic diagram of a connection between an isolation structure and a first power supply according to an embodiment of the present disclosure.

FIG. 13 is yet still another schematic diagram of a connection between an isolation structure and a first power supply according to an embodiment of the present disclosure.

FIG. 14 is a schematic diagram of a first connection hole according to an embodiment of the present disclosure.

FIG. 15 is another schematic diagram of a first connection hole according to an embodiment of the present disclosure.

FIG. 16 is still another schematic diagram of a first connection hole according to an embodiment of the present disclosure.

FIG. 17 is yet still another cross-sectional view of a display panel according to an embodiment of the present disclosure.

FIG. 18 is a schematic diagram of an isolation structure according to an embodiment of the present disclosure.

FIG. 19 is another schematic diagram of an isolation structure according to an embodiment of the present disclosure.

FIG. 20 is still another schematic diagram of a connection between an isolation structure and a first power supply according to an embodiment of the present disclosure.

FIG. 21 is yet still another schematic diagram of a connection between an isolation structure and a first power supply according to an embodiment of the present disclosure.

### DETAILED DESCRIPTION OF THE EMBODIMENTS

In some display panels in related technologies, by provided an isolation structure in the display panel, an organic light-emitting material layer between adjacent pixel openings is disconnected during a full-surface evaporation process by the isolation structure. Thus, through patterning etching after the full-surface layer evaporation, different organic light-emitting material layers with different light-emitting colors may be formed in different pixel openings.

Upon investigation of inventors, it has been found that in the display panel, the isolation structure is conductive; a cathode of a light-emitting device located within an isolation opening is connected to the isolation structure and is thereby connected to wiring of a Voltage Source Supply (Vss) through the isolation structure. The Vss and the isolation structure are arranged in different layers, and are connected through a via hole with relatively high current density, easily causing screen burn-in and degrading a yield of the display panel.

In view of this, embodiments of the present disclosure provide a solution to reduce the risk of screen burn-in on display panels. The following provides a detailed description of the solution provided by the embodiments of the present disclosure.

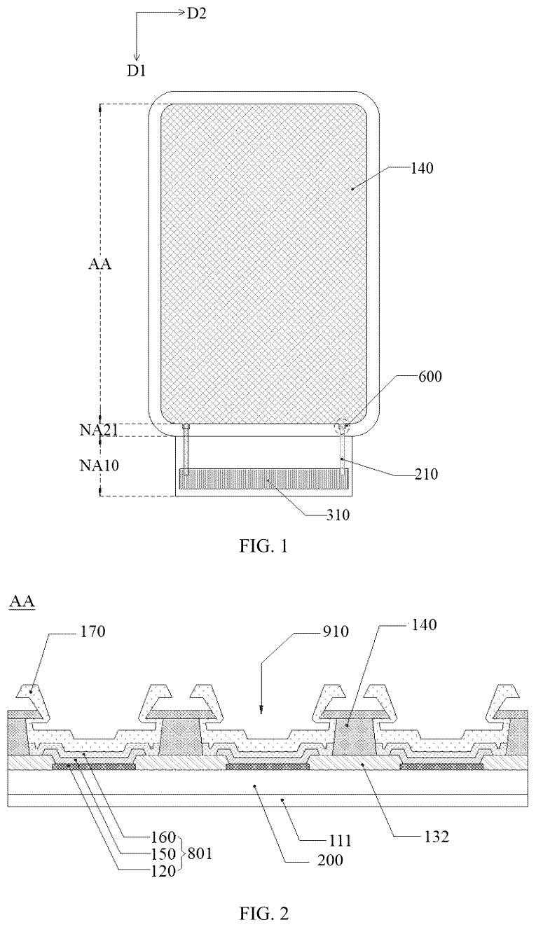

Referring to FIG. 1, FIG. 1 is a schematic diagram of a display panel according to the embodiment. The display panel may include a display region AA and a bonding region NA10 located on a side of the display region AA.

In one embodiment, in the embodiments of the present disclosure, the display region AA includes a light-emitting side and a back-light side facing away from each other. The bonding region NA10 is configured to arrange an integrated circuit chip or be connected with other circuit boards. The bonding region NA10 may be folded to the back-light side of the display panel.

Referring to FIGS. 2 to 4, a display panel provided by an embodiment of the present disclosure may include a substrate 111, a wiring layer 200, and an isolation structure 140.

In an embodiment of the present disclosure, a material of the substrate 111 may include a rigid material, such as glass. In one embodiment, the material of the substrate 111 may include a flexible material, such as Polyimide (PI).

In one embodiment, an array function layer may further be provided on a side of the substrate 111. The array function layer may include a plurality of film layers, such as a buffer layer, an active layer, a plurality of conductive layers, a plurality of insulating layers 130, and a planarization layer, etc. The plurality of film layers of the array function layer may form a plurality of Thin Film Transistors (TFTs) and wiring structures at different positions. The TFTs cooperate with each other to form a plurality of pixel driving units or driving circuits, and the wiring structures are configured to provide signals or voltages to the circuits.

The wiring layer 200 is located on a side of the substrate 111. The wiring layer 200 may be a conductive layer in the array function layer. The wiring layer 200 includes at least one first power line 210. In one embodiment, in the embodiments of the present disclosure, the first power line 210 may be configured to transmit the Vss. A first end of the first power line may be connected to the bonding region NA10. For example, the bonding region NA10 is provided with a plurality of bonding contacts 310. The first end of the first power line 210 may be connected to the bonding contact 310.

The isolation structure 140 is located on a side, facing away from the substrate 111, of the wiring layer 200. At least part of the isolation structure 140 is located in the display region AA. For example, a plurality of isolation openings 910 are defined by the isolation structure 140 in the display region AA. The isolation structure 140 is electrically connected to the bonding region NA10 through the at least one first power line 210.

In one embodiment, in the display region AA, the display panel further includes a light-emitting device 801 at least partially located in the isolation opening 910. The light-emitting device 801 includes a first electrode 120, a light-emitting function layer 150, and a second electrode 160 stacked in a direction away from the substrate 111.

In one embodiment, the first electrode 120 may be connected to a pixel driving circuit in the array function layer. The second electrode 160 may be connected to the first power line 210, which is configured to transmit the Vss, through the isolation structure 140. When there is an electric potential difference between the first electrode 120 and the second electrode 160, the light-emitting function layer 150 located between the first electrode 120 and the second electrode 160 is driven to emit light.

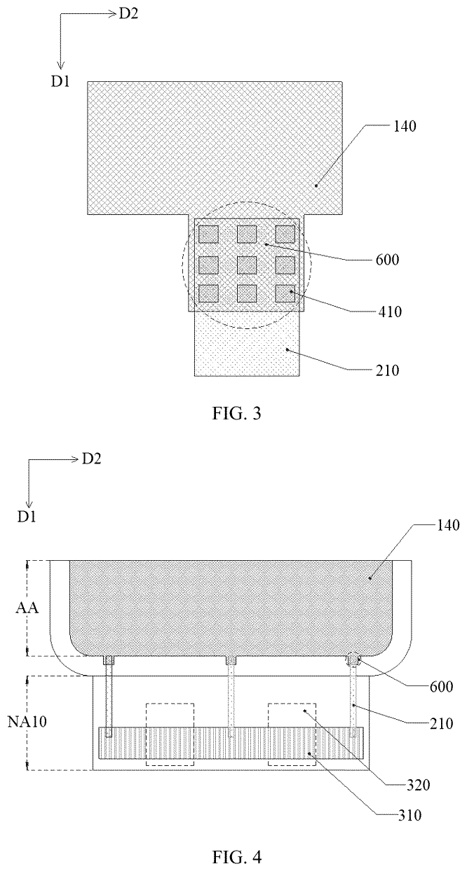

Referring to FIG. 3, the isolation structure 140 includes at least one connection region 600, and an orthographic projection of the connection region 600 on the substrate 111 is located within an orthographic projection of the first power line 210 on the substrate 111. The at least one connection region 600 includes a plurality of first connection holes 410, and the isolation structure 140 is electrically connected to a second end of the first power line 210 through the first connection hole 410. Thus, the isolation structure 140 is electrically connected to the bonding region NA10 through the first power line 210.

A total area of the plurality of first connection holes 410 is greater than a total area of an overlapping region between the first power line 210 and the bonding region NA10.

The total area of the plurality of first connection holes 410 may be a total area of orthographic projections of the plurality of first connection holes 410 on the substrate 111. The total area of the overlapping region between the first power line 210 and the bonding region NA10 may be a total area of the overlapping region between an orthographic projection of the first power line 210 on the substrate 111 and an orthographic projection of the plurality of bonding contacts 310 in the bonding region NA10 on the substrate 111.

Based on the above-mentioned design, by setting the total area of the connection via holes connecting the isolation structure 140 and the first power line 210 to be greater than the total area of the overlapping region between the first power line 210 and the bonding region NA10, an overlapping region between the isolation structure 140 and the first power line 210 is increased, thereby reducing the risk of screen burn-in at a connection contact between the isolation structure 140 and the first power line 210 due to high current density.

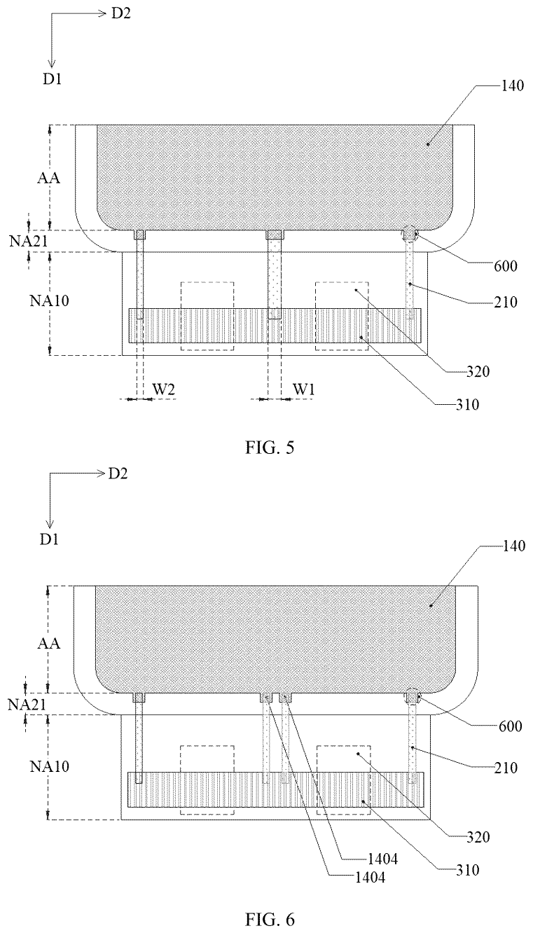

In some possible implementation, referring to FIGS. 4 and 5, the display panel further includes a first frame region NA21 located between the display region AA and the bonding region NA10. At least three connection regions 600 are located within the first frame region NA21. The isolation structure 140 is connected to at least three first power lines 210 of the at least one first power line 210 through the at least three connection regions 600 in one-to-one correspondence.

That is, in the embodiments of the present disclosure, the isolation structure 140 may be connected to the at least three first power lines 210 of the at least one first power line 210 in the first frame region NA21. Thus, by increasing a quantity of connection contacts between the isolation structure 140 and the first power lines 210 has been increased, voltage distribution on a side, closer to the first frame, of the isolation structure 140 may be more uniform, thereby reducing a risk of a large difference in voltage drop between different positions of the isolation structure 140.

In one embodiment, the bonding region NA10 includes at least two sub-bonding regions 320, and a quantity of the at least one connection region 600 is greater than or equal to a quantity of the sub-bonding regions 320.

In some possible implementation, the display region AA, the first frame region NA21, and the bonding region NA10 are arranged in sequence along a first direction D1. At least two sub-bonding regions 320 are arranged along a second direction D2, and the first direction D1 intersects with the second direction D2.

In one embodiment, the bonding contact 310 may be located on a side, facing away from the display region AA, of the sub-bonding region 320. In the second direction D2, two connection regions 600 of the at least one connection region 600 are respectively located on two sides of the first frame region NA21, and at least one first power line 210 is located between two adjacent sub-bonding regions 320 of the at least two sub-bonding regions 320.

That is, in the embodiments of the present disclosure, at least part of the first power line 210 may extend from the bonding region NA10 along the first direction D1 to the first frame region NA21 through a gap between two adjacent sub-bonding regions 320 of the at least two sub-bonding regions 320, to connect the isolation structure 140 with the bonding region NA10. Thus, positions between the sub-bonding regions 320 may be fully utilized to set the first power line 210, increasing the quantity of connection regions between the isolation structure 140 and the first power line 210.

In one embodiment, the sub-bonding region 320 may be provided with a driver chip.

In the embodiments of the present disclosure, when the bonding region NA10 is folded to the backside of the display region AA, the first power line 210 located in the bonding region NA10 may also be bent accordingly. In this case, an extension direction of the first power line 210 is consistent with a bending and folding direction of the bonding region NA10.

In some possible implementation, referring to FIG. 5, in the second direction D2, a width W1 of a connection region 600 located between two adjacent sub-bonding regions 320 of the at least two sub-bonding regions 320 is greater than a width W2 of connection regions 600 located on both sides of the first frame region NA21.

For example, in the second direction D2, the width W1 of the connection region 600 located between two adjacent sub-bonding regions 320 of the at least two sub-bonding regions 320 is twice the width W2 of the connection regions 600 located on both sides of the first frame region NA21.

Thus, the overlapping region between the first power line 210 and the isolation structure 140 may be increased, reducing a connection resistance and the risk of screen burn-in.

In some possible implementation, referring to FIG. 6, in the second direction D2, the connection regions 600 located between two adjacent sub-bonding regions 320 of the at least two sub-bonding regions 320 includes two sub-connection regions 1404 spaced apart along the second direction D2.

In the second direction D2, a width of the sub-connection region 1404 is equal to the width of the connection region 600 located on two sides of the first frame region NA21.

In one embodiment, the two sub-connection regions 1404 of the same connection region 600 are respectively connected to different bonding contacts 310 of the bonding region NA10. For example, the two sub-connection regions 1404 of the same connection region 600 are respectively connected to the bonding contacts 310 belonging to different circuit boards.

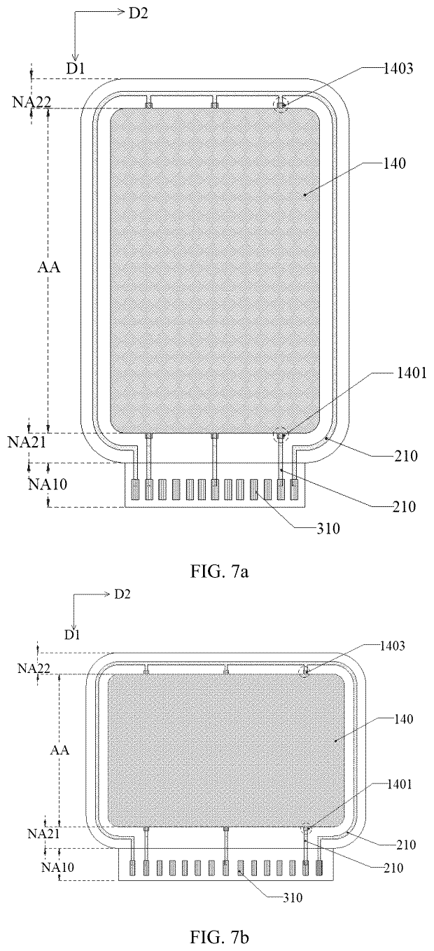

In some possible implementation, referring to FIGS. 7a and 7b, the display panel further includes a first frame region NA21 and a second frame region NA22 arranged opposite to each other. The first frame region NA21 is located between the display region AA and the bonding region NA10, and the second frame region NA22 is located on a side, further away from the first frame region NA21, of the display region AA.

The at least one connection region 600 includes at least one first connection region 1401 and at least one second connection region 1403. The at least one first connection region 1401 is located in the first frame region NA21, and the at least one second connection region 1403 is located in the second frame region NA22.

That is, in the embodiments of the present disclosure, the isolation structure 140 may be respectively connected to different first power lines 210 in the first frame region NA21 and the second frame region NA22. Thus, by increasing a quantity of connection regions, the connection resistance may be reduced and the distribution of the connection region may be made more uniform, improving voltage uniformity between a side, closer to the first frame region NA21, of isolation structure 140 and a side, closer to the second frame region NA22, of isolation structure 140 and ensuring display uniformity of the display panel.

In one embodiment, the display region AA, the first frame region NA21, and the bonding region NA10 are arranged along the first direction D1 in sequence. In the second direction D2, two first connection regions 1401 of the at least one first connection region 1401 are respectively located on two sides of the first frame region NA21. The first direction D1 intersects with the second direction D2.

In one embodiment, the isolation structure 140 is electrically connected to different first power lines 210 through the first connection region 1401 and the second connection region 1403. Thus, it is possible to prevent a single first power line 210 from being overloaded.

In some possible implementation, in the first direction D1, a first connection region 1401 and a second connection region 1403 are located on a same straight line.

In one embodiment, a quantity of the first connection region 1401 is equal to a quantity of the second connection region 1403.

Thus, uniformity of the connection regions on the side, closer to the first frame region NA21, of isolation structure 140 and the side, closer to the second frame region NA22, of isolation structure 140 may be improved, thereby enhancing the overall voltage uniformity of the isolation structure 140.

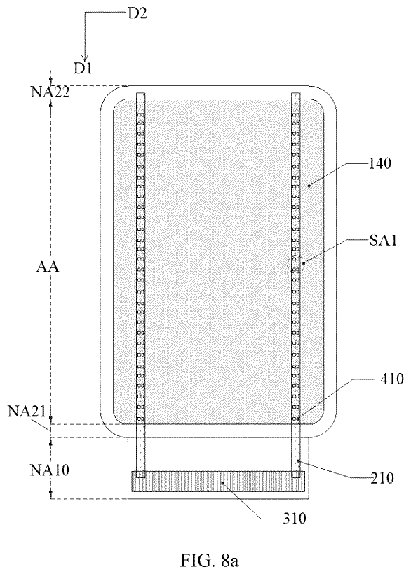

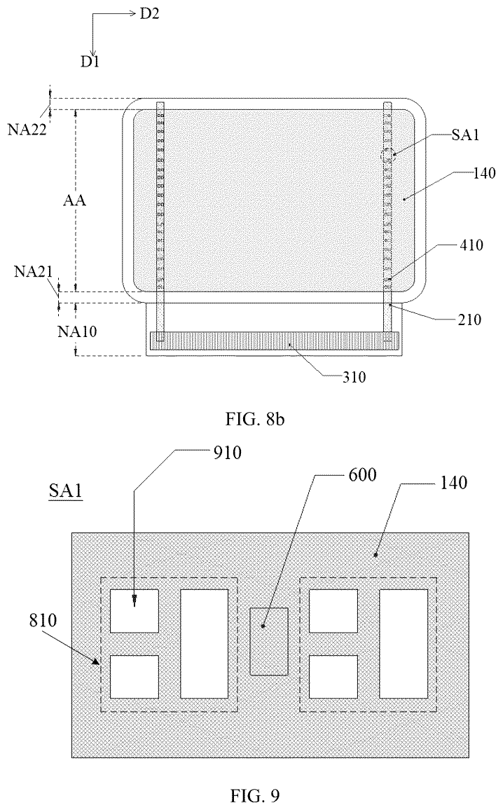

In some possible implementation, referring to FIGS. 8a and 8b, the display panel further includes a first frame region NA21 located between a display region AA and a bonding region NA10. The display region AA, the first frame region NA21 and the bonding region NA10 are arranged in sequence along a first direction D1. A first power line 210 extends from the first frame region NA21 to the display region AA along the first direction D1, and at least part of a plurality of first connection holes 410 are located in the display region AA.

That is, in the embodiments of the present disclosure, the first power line 210 can extend to the display region AA to connect to the isolation structure 140. Thus, by increasing a quantity of the connection regions connecting the isolation structure 140 to the first power line 210, voltage uniformity at different positions of the isolation structure 140 within the display region AA may be improved.

In one embodiment, the display panel may further include a second frame region NA22 located on a side, further away from the first frame region NA21, of the display region AA. The first power line 210 extends from the first frame region NA21 along the first direction D1 to the second frame region NA21 through the display region AA.

In one embodiment, all of the plurality of first connection holes 410 are located in the display region AA.

In one embodiment, referring to FIG. 9, FIG. 9 is an enlarged schematic diagram of a position SA1 shown in FIG. 8b. An orthographic projection of the plurality of first connection holes 410 on the substrate 111 is located between orthographic projections of adjacent isolation openings of two or more isolation openings 910 on the substrate 111. Thus, it is possible to prevent the first connection hole 410 from affecting the isolation opening 910, thereby increasing a pixel density of the display panel.

In one embodiment, the orthographic projection of the plurality of first connection holes 410 on the substrate 111 is located between orthographic projections of two adjacent repeating pixel units on the substrate 111. For example, in the embodiments of the present disclosure, a red, a green, and a blue light-emitting device 801 may form a pixel unit, and a plurality of pixel units are repeatedly arranged. In this case, the first connection hole 410 may be arranged between the repeating pixel units.

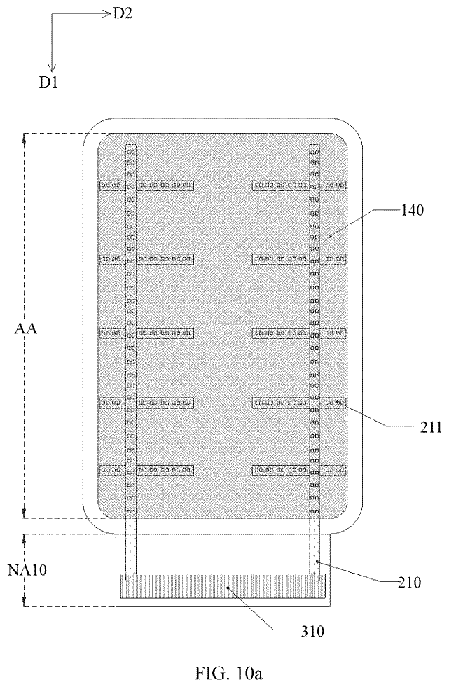

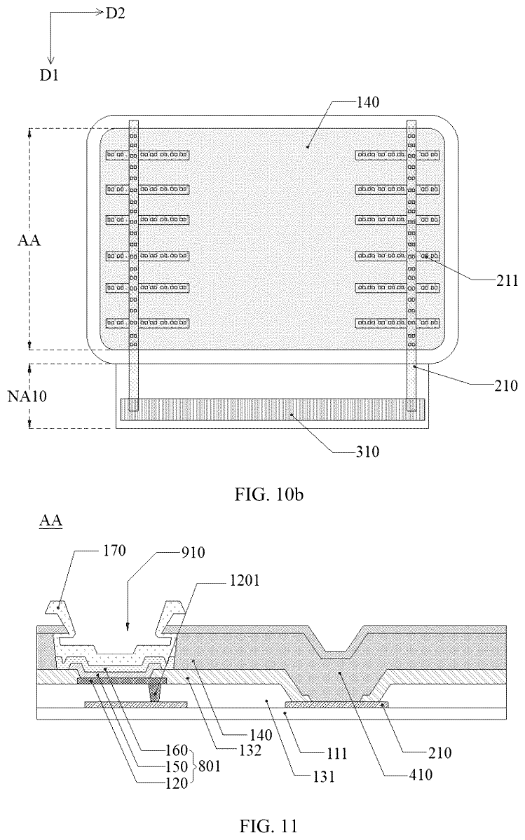

In one embodiment, referring to FIGS. 10a and 10b, the first power line 210 may further includes a plurality of branches 211 located in the display region AA and the plurality of branches 211 extend along a different direction from the first direction D1. The isolation structure 140 is connected to at least part of a branch 211 through the plurality of first connection holes 410. Thus, by further increasing the quantity of connection regions between the isolation structure 140 and the first power supply, the voltage uniformity at different positions of the isolation structure 140 within the display region AA may be improved.

In some possible implementation, referring to FIG. 11, a first electrode 120 is electrically connected to at least part of wiring in the wiring layer 200 through a second connection hole 1201. In this case, an area of an orthographic projection of a first connection hole 410 on the substrate 111 is greater than an area of an orthographic projection of the second connection hole 1201 on the substrate 111.

For example, the area of the orthographic projection of the first connection hole 410 on the substrate 111 is greater than or equal to 9 μm².

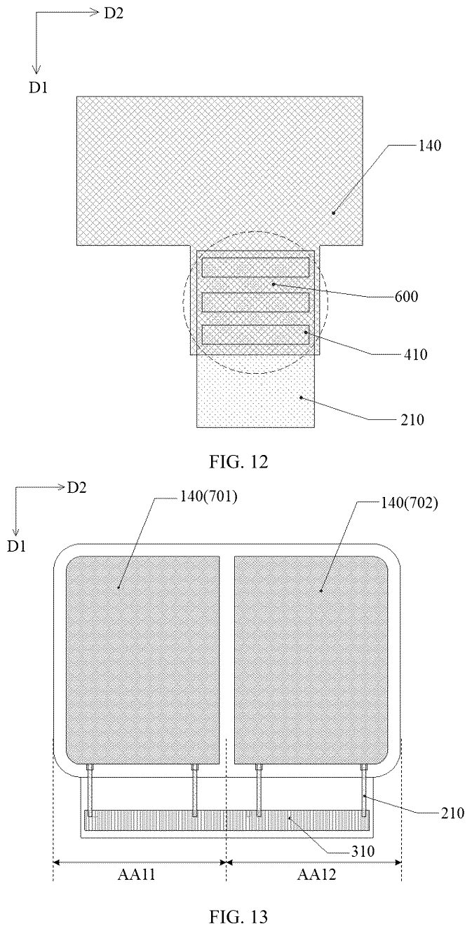

In some possible implementation, referring to FIG. 12, the display region AA and the bonding region NA10 are arranged along a first direction D1. An orthographic projection of the first connection hole 410 on the substrate 111 is rectangular, and a long side of the rectangle extends along a second direction D2, which is different from the first direction D1.

In some possible implementation, referring to FIG. 13, the display region AA and the bonding region NA10 are arranged along a first direction D1. The isolation structure 140 includes a first sub-isolation structure 701 and a second sub-isolation structure 702 arranged and spaced apart along a second direction D2. The first sub-isolation structure 701 and the second sub-isolation structure 702 are electrically connected to different first power lines 210. The first direction D1 intersects with the second direction D2.

In one embodiment, the display region AA includes a first sub-display region AA11 and a second sub-display region AA12 arranged along the second direction D2. The first sub-isolation structure 701 is located in the first sub-display region AA11, and the second sub-isolation structure 702 is located in the second sub-display region AA12.

For example, the display panel provided by the embodiments of the present disclosure may be a foldable display panel, and a gap between the sub-isolation structures is a folding region of the display panel. Different sub-isolation structures are electrically connected to different first power lines 210, thus enabling independent provision of electrical power to the two sub-isolation structures. That is, when display in the first sub-display region AA11 is disabled, but display in the second sub-display region AA12 is enabled, it is not necessary to supply electrical energy to the first sub-isolation structure 701 located in the first sub-display region AA11 through the first power line 210. Instead, electrical energy may be supplied to the second sub-isolation structure 702 located in the second sub-display region AA12 through another first power line 210, therefore reducing overall power consumption of the display panel.

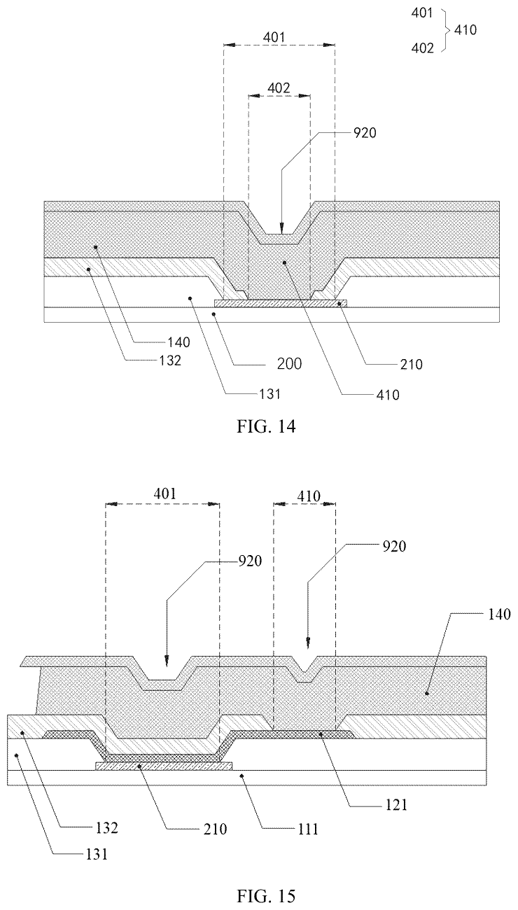

In some possible implementation, referring to FIG. 14, the display panel may further include a first insulating layer 131 and a second insulating layer 132 located between the isolation structure 140 and the wiring layer 200.

The first insulating layer 131 is provided with a first via 401, and the second insulating layer 132 is provided with a second via 402. An orthographic projection of the second via 402 on the substrate 111 is located within an orthographic projection of the first via 401 on the substrate 111. The first via 401 and the second via 402 are in communication to form the plurality of first connection holes 410. At least part of the first power line 201 is exposed by the plurality of first connection holes 410.

At least part of the isolation structure 140 extends into the plurality of first connection holes 410 to electrically connect to the first power line 210.

In one embodiment, in the embodiments of the present disclosure, the first insulating layer 131 may be a planarization layer formed of an organic material, and the second insulating layer 132 may be a pixel defining layer formed of an inorganic material. The second insulating layer 132 can cover a side wall, facing the first via 401, of the first insulating layer 131, thereby preventing the side wall of the first insulating layer 131 from being exposed and reducing the risk of water vapor invading the first insulating layer 131.

In one embodiment, the isolation structure 140 may include a recessed portion 920 recessed towards the substrate 111. An orthographic projection of the recessed portion 920 on the substrate 111 at least partially overlaps with an orthographic projection of a first connection hole 410 on the substrate 111.

For example, the first insulating layer 131 and the second insulating layer 132 are provided between the isolation structure 140 and the wiring layer 200. The isolation structure 140 is connected to a first power line 210 in the wiring layer 200 through a first connection hole 410 that extends through the first insulating layer 131 and the second insulating layer 132. In this case, a recessed portion 920 may be formed at a position, corresponding to the first connection hole 410, of the isolation structure 140 due to an entrapment in the first connection hole 410.

In some possible implementation, referring to FIG. 15, the display panel may further include a first insulating layer 131 and a second insulating layer 132 located between the isolation structure 140 and the wiring layer 200, and a first via 401 extends through the first insulating layer 131. The plurality of first connection holes 410 extend through the second insulating layer 132.

The display panel may further include a first connection wiring line 121 located between the first insulating layer 131 and the second insulating layer 132.

At least part of the first power line 210 is exposed by the first via 401. At least part of the first connection wiring line 121 extends into the first via 401 to electrically connect to the first power line 210. At least part of the first connection wiring line 121 is exposed by the first connection holes 410, and at least part of the isolation structure 140 extends into the first connection hole 410 to electrically connect to the first connection wiring line 121.

In one embodiment, an orthographic projection of the first via 401 on the substrate 111 is staggered with orthographic projections of the plurality of first connection holes 410 on the substrate 111.

That is, in the embodiments of the present disclosure, the isolation structure 140 may be connected to the first power line 210 through the first connection wiring line 121. The first connection wiring line 121 may be arranged in a same layer as the first electrode 120 of the light-emitting device 801. Thus, flexibility of arrangement of the first connection hole 410 may be enhanced.

In one embodiment, the isolation structure 140 may include a recessed portion 920 recessed towards the substrate 111, and an orthographic projection of this recessed portion 920 on the substrate 111 at least partially overlaps with an orthographic projection of the first connection hole 410 on the substrate 111. In one embodiment, the recessed portions 920 may be formed at the positions, corresponding to both the first via 401 and the first connection hole 410, of the isolation structure 140.

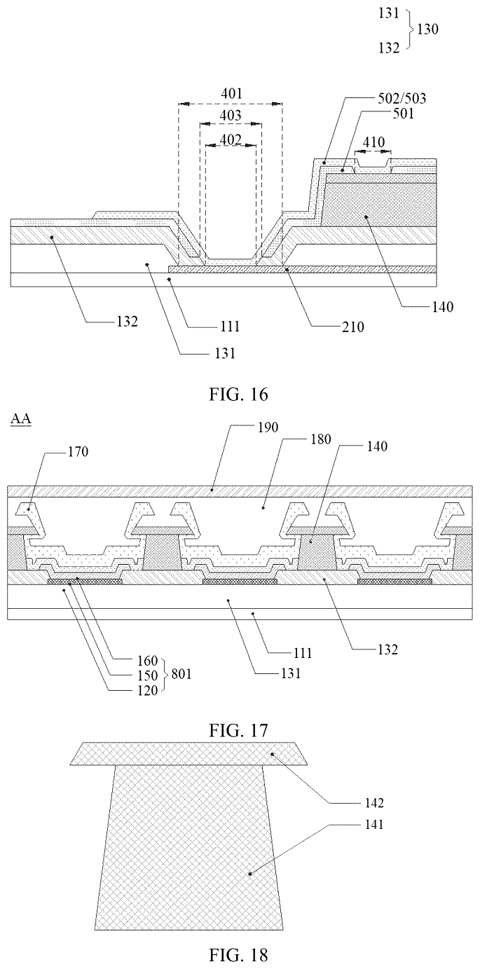

In some possible implementation, referring to FIG. 16, the display panel may further include a first insulating layer 131 and a second insulating layer 132 located between the isolation structure 140 and the wiring layer 200. The display panel may further include a third insulating layer 501 located on the side, facing away from the substrate 111, of the isolation structure 140, and a touch-control wiring layer 503 located on the side, facing away from the substrate 111, of the third insulating layer 501.

The first insulating layer 131 includes the first via 401, the second insulating layer 132 includes the second via 402, and the third insulating layer 501 includes a third via 403.

An orthographic projection of the second via 402 on the substrate 111 is located within an orthographic projection of the first via 401 on the substrate 111. The first via 401, the second via 402, and the third via 403 are in communication to expose at least part of the first power line 210. An orthographic projection of the isolation structure 140 on the substrate 111 is staggered with orthographic projections of the first via 401, the second via 402, and the third via 403 on the substrate 111.

A first connection hole 410 may extend through the third insulating layer 501. For example, the third insulating layer 501 covers the isolation structure 140, and the isolation structure 140 is exposed by the first connection hole 410.

The touch-control wiring layer 503 may include a touch-control wiring line and a second connection wiring line 502 set in a same layer. A t least part of the second connection wiring line 502 extends into the first via 401, the second via 402 and the third via 403 to electrically connect to the first power line 210. At least part of the second connection wiring line 502 is electrically connected to the isolation structure 140 through the first connection hole 410.

That is, in the embodiments of the present disclosure, the second connection wiring line 502 in the touch-control wiring layer 503 are respectively connected to the first power line 210 and the isolation structure 140, thereby achieving an electrical connection between the first power line 210 and the isolation structure 140.

In some possible implementation, referring to FIG. 17, the display panel may further include a plurality of encapsulation units 170, and the plurality of encapsulation units 170 are located on a side, facing away from the substrate 111, of a plurality of light-emitting device 801 correspondingly.

In one embodiment, the display panel further includes a first encapsulation layer 180 and a second encapsulation layer 190 arranged in sequence on the side, facing away from the substrate 111, of the encapsulation unit 170 and the isolation structure 140.

In one embodiment, a material of the encapsulation unit and a material of the second encapsulation layer include an inorganic material, and a material of the first encapsulation layer includes an organic material.

In some possible implementation, referring to FIG. 18, the isolation structure 140 includes a supporting portion 141, and a shielding portion 142 located on a side, facing away from the substrate 111, of the supporting portion 141. An orthographic projection of an end, closer to the isolation opening 910, of the supporting portion 141 on the substrate 111 is located within an orthographic projection of the shielding portion 142 on the substrate 111.

In one embodiment, under a same etching condition, an etch resistance of the supporting portion 141 is weaker than an etch resistance of the shielding portion 142.

In one embodiment, a material of the supporting portion includes Al, or a material of the shielding portion includes Ti.

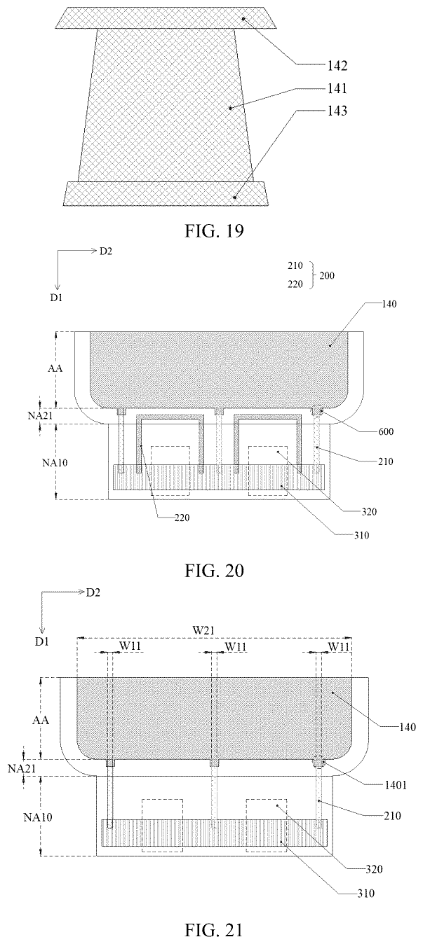

In one embodiment, referring to FIG. 19, the isolation structure may further include a transition portion located 143 between the supporting portion 141 and the substrate 111.

In one embodiment, an orthographic projection of the transition portion 143 on the substrate 111 is located within an orthographic projection of an end, closer to the isolation opening 910, of the shielding portion 142 on the substrate 111.

In one embodiment, a material of the transition portion includes Mo.

In some possible implementation, referring to FIG. 20, the wiring layer 200 may further include a second power wiring line 220 extending from the bonding region NA10 to the first frame region NA21. The second power wiring line 220 may be configured to transmit Voltage Drain Drain (Vdd), and be electrically connected to the pixel driving circuit in the display region AA. FIG. 20 does not show a connection path between the second power line 220 and the pixel driving circuit in the display region AA, which will not be described in the embodiments of the present disclosure.

Referring to FIG. 21, the present disclosure further provides a display panel. The display panel includes a display region AA and a bonding region NA10 located on a side of the display region AA. The display panel includes a substrate 111, a wiring layer 200, and an isolation structure 140.

The wiring layer 200 is located on a side of the substrate. The wiring layer includes at least one first power line 210, and a first end of the first power line 210 is connected to the bonding region NA10. For example, the bonding region NA10 is arranged with a plurality of bonding contacts 310. The first end of the first power line 210 may be connected to the bonding contact 310.

The isolation structure 140 is located on a side, facing away from the substrate 111, of the wiring layer 200. At least part of the isolation structure 140 is located in the display region AA. For example, a plurality of isolation openings 910 are defined by the isolation structure 140 located in the display region AA. The isolation structure 140 is electrically connected to the bonding region NA10 through at least one of the first power lines 210.

The isolation structure 140 includes at least one connection region 600. The isolation structure 140 is connected to the first power line 210 in the at least one connection region 600. A total area of the at least one connection region 600 is greater than or equal to 0.1% of an area of the display region AA.

For example, an orthographic projection of the connection region 600 on the substrate 111 is located within an orthographic projection of the first power lines 210 on the substrate 111. The at least one connection region 600 includes a plurality of first connection holes 410. The isolation structure 140 is electrically connected to the first power line 410 through the plurality of first connection holes 210. The total area of the at least one connection region 600 is exactly a total area covered by a region arranging the plurality of first connection holes 410.

Based on the above design, by increasing the area of the at least one connection region 600, a connection resistance between the isolation structure 140 and the first power supply is reduced, thereby reducing the risk of screen burn-in on the display panel.

In some possible implementation, the display region AA and the bonding region NA10 are arranged along the first direction D1. The first power line 210 extends from the bonding region NA10 along the first direction D1 to connect to the isolation structure 140.

A sum of widths W1 of the at least one connection region 600 in a second direction D2 is greater than or equal to 1/20 of a length of the display region AA in the second direction D2, and the first direction D1 intersects with the second direction D2.

In one embodiment, the first direction D1 is perpendicular to the second direction D2.

In some possible implementation, the display panel may further include a first frame region NA21 located between the display region AA and the bonding region NA10. The at least one connection region 600 includes at least three connection regions 600 located within the first frame region NA21. The isolation structure 140 is connected to at least three first power lines 210 of the at least one first power line 210 through the at least three connection regions 600 in one-to-one correspondence.

In one embodiment, the bonding region NA10 includes at least two sub-bonding regions 320, and a quantity of the at least one connection region 600 is greater than or equal to a quantity of the sub-bonding regions 320.

In one embodiment, the display region AA, the first frame region NA21, and the bonding region NA10 are arranged in sequence along the first direction D1. The at least two of the sub-bonding regions 320 are arranged along the second direction D2, and the first direction D1 intersects with the second direction D2.

In one embodiment, a bonding contact 310 may be located on a side, further away from the display region AA, of the sub-bonding region 320. In the second direction D2, the two bonding regions NA10 are respectively located on two sides of the first frame region NA21, and at least one of the first power lines 210 is located between two adjacent sub-bonding regions 320 of the at least two sub-bonding regions 320.

The present disclosure further provides a display panel. The display panel includes a display region AA and a bonding region NA10 located on a side of the display region AA. The display panel includes a substrate 111, a wiring layer 200, and an isolation structure 140.

The wiring layer 200 is located on a side of the substrate. The wiring layer includes a first power line 210, and a first end of the first power line 210 is connected to the bonding region NA10.

The isolation structure 140 is located on a side, facing away from the substrate 111, of the wiring layer 200. At least part of the isolation structure 140 is located in the display region AA. For example, a plurality of isolation openings 910 are defined by the isolation structure 140 in the display region AA. The isolation structure 140 is electrically connected to the bonding region NA10 through at least one first power line 210.

The isolation structure 140 may include at least one connection region 600. An orthographic projection of the connection region 600 on the substrate 111 is located within an orthographic projection of the first power line 210 on the substrate 111. The at least one connection region 600 includes a plurality of first connection holes 410. The isolation structure 140 is electrically connected to the first power line 410 through the plurality of first connection holes 210. A total area of the plurality of first connection holes 410 connected to a second end of the first power line 210 is greater than a total area of an overlapping region between the first end of the same first power line 210 and the bonding region NA10, thereby ensuring that the total area of all first connection holes 410 is greater than a total area of the overlapping region between all first power lines 210 and the bonding region NA10.

The present disclosure further provides a display device including the display panel provided by the present disclosure. The display device may include devices such as mobile phones, tablets, smart wearable devices, televisions, laptops, monitors, etc., with a display function.

In view of above, by setting a total area of overlapping regions of connection holes between an isolation structure and a first power line to be greater than a total area of an overlapping region between the first power line and a bonding region, a connection area between the isolation structure and the first power line is increased, thereby reducing a risk of screen burn-in at a connection contact between the isolation structure and the first power line due to high current density.

The above-described embodiments may be combined in any way. For the sake of conciseness, not every possible combination of the individual embodiments has been described; nevertheless, any combination that does not give rise to contradiction shall be regarded as falling within the scope of the present disclosure.

What is claimed is:

1. A display panel, provided with a display region and a bonding region located beside the display region; the display panel comprising:
a substrate;
a wiring layer located on a side of the substrate; and
an isolation structure located on a side, facing away from the substrate, of the wiring layer;
wherein the wiring layer comprises at least one first power line, and a first end of the first power line is connected to the bonding region; at least part of the isolation structure is located in the display region and electrically connected to the bonding region through the at least one first power line; the isolation structure comprises at least one connection region, an orthographic projection of the connection region on the substrate is located within an orthographic projection of the first power line on the substrate, the connection region comprises a plurality of first connection holes, the isolation structure is electrically connected to a second end of the first power line through the plurality of first connection holes, and a total area of the plurality of first connection holes is greater than a total area of an overlapping region between the first power line and the bonding region.

2. The display panel according to claim 1, further comprising a first frame region located between the display region and the bonding region, wherein at least three connection regions of the at least one connection region are located within the first frame region and are respectively connected to at least three first power lines of the at least one first power line in one-to-one correspondence;
the bonding region comprises at least two sub-bonding regions, and a quantity of the at least one connection region is greater than or equal to a quantity of the sub-bonding regions; and
the sub-bonding region is provided with a driver chip.

3. The display panel according to claim 2, wherein the display region, the first frame region, and the bonding region are arranged in sequence along a first direction, the at least two sub-bonding regions are arranged along a second direction, and the first direction intersects with the second direction; and
in the second direction, two connection regions of the at least one connection region are respectively located on two sides of the first frame region, and the at least one first power line is located between two adjacent sub-bonding regions of the at least two sub-bonding regions.

4. The display panel according to claim 3, wherein in the second direction, a width of the connection region located between two adjacent sub-bonding regions of the at least two sub-bonding regions is greater than a width of the connection regions located on two sides of the first frame region.

5. The display panel according to claim 4, wherein in the second direction, the connection region located between the two adjacent sub-bonding regions of the at least two sub-bonding regions comprises two sub-connection regions spaced apart along the second direction;
in the second direction, a width of the sub-connection region is equal to the width of the connection regions located on two sides of the first frame region; and
the two sub-connection regions of the same connection region are respectively connected to different bonding contacts of the bonding region.

6. The display panel according to claim 1, further comprising a first frame region and a second frame region arranged opposite to each other, wherein the first frame region is located between the display region and the bonding region, and the second frame region is located on a side, further away from the first frame region, of the display region;
the at least one connection region comprises at least one first connection region and at least one second connection region, the first connection region is located in the first frame region, and the second connection region is located in the second frame region;
the display region, the first frame region, and the bonding region are arranged along the first direction; in the second direction, two first connection regions of the at least one first connection region are respectively located on two sides of the first frame region; and the first direction intersects with the second direction;
the first connection region and the second connection region are respectively connected to different first power lines;
in the first direction, one of the at least one first connection regions and one of the at least one second connection regions are located on a same straight line; and
a quantity of the at least one first connection region is equal to a quantity of the at least one second connection region.

7. The display panel according to claim 1, further comprising a first frame region located between the display region and the bonding region, wherein the display region, the first frame region and the bonding region are arranged in sequence along the first direction, the first power line extends from the first frame region to the display region along the first direction, and at least part of the plurality of first connection holes are located in the display region;
the display panel further comprises a second frame region located on a side, further away from the first frame region, of the display region, the first power line extends from the first frame region along the first direction through the display region to the second frame region;
orthographic projections of the plurality of first connection holes on the substrate are located between orthographic projections of adjacent isolation openings of two or more isolation openings on the substrate;
the orthographic projections of the plurality of first connection holes on the substrate are located between orthographic projections of two adjacent repeating pixel units on the substrate; and
the first power line further comprises a branch located in the display region and extending along a different direction from the first direction, and the isolation structure is connected with at least part of the branch through the plurality of first connection holes.

8. The display panel according to claim 1, further comprising a plurality of light-emitting devices, wherein at least part of a light-emitting device is located in an isolation opening, the light-emitting device comprises a first electrode, a light-emitting function layer and a second electrode stacked in a direction away from the substrate; the first electrode is electrically connected to at least part of wiring in the wiring layer through a second connection hole;
the second electrode is electrically connected to the isolation structure;
an area of an orthographic projection of a first connection hole on the substrate is greater than an area of an orthographic projection of the second connection hole on the substrate;
an area of the orthographic projection of the first connection hole on the substrate is greater than or equal to 9 μm²;
the display panel further comprising a plurality of encapsulation units, wherein an encapsulation unit is located on a side, facing away from the substrate, of a corresponding one of the plurality of light-emitting devices;
further comprising a first encapsulation layer and a second encapsulation layer arranged in sequence on a side, facing away from the substrate, of the plurality of encapsulation units and the isolation structure;
wherein a material of the encapsulation unit and a material of the second encapsulation layer comprise an inorganic material; and a material of the first encapsulation layer comprises an organic material.

9. The display panel according to claim 1, wherein the display region and the bonding region are arranged along the first direction, an orthographic projection of a first connection hole on the substrate is rectangular, and a long side of the rectangle extends along a second direction different from the first direction.

10. The display panel according to claim 1, wherein the display region and the bonding region are arranged along the first direction, the isolation structure comprises a first sub-isolation structure and a second sub-isolation structure arranged and spaced apart along a second direction, the first sub-isolation structure and the second sub-isolation structure are electrically connected to different first power lines, the first direction intersects with the second direction; and
the display region comprises a first sub-display region and a second sub-display region arranged along the second direction, the first sub-isolation structure is located in the first sub-display region, and the second sub-isolation structure is located in the second sub-display region.

11. The display panel according to claim 1, further comprising a first insulating layer and a second insulating layer located between the isolation structure and the wiring layer;
wherein the first insulating layer comprises a first via, the second insulating layer comprises a second via, an orthographic projection of the second via on the substrate is located within an orthographic projection of the first via on the substrate, the first via communicates with the second via to form a first connection hole, and at least part of the first power line is exposed by the first connection hole;
at least part of the isolation structure extends into the first connection hole to electrically connect to the first power line; and
the isolation structure comprises a recessed portion recessed towards the substrate, an orthographic projection of the recessed portion on the substrate at least partially overlaps with an orthographic projection of the first connection hole on the substrate.

12. The display panel according to claim 1, further comprising a first insulating layer and a second insulating layer located between the isolation structure and the wiring layer, and a first via extending through the first insulating layer, wherein the plurality of first connection holes extend through the second insulating layer;
further comprising a first connection wiring line located between the first insulating layer and the second insulating layer;
wherein at least part of the first power line is exposed by the first via, at least part of the first connection wiring line extends into the first via to electrically connect to the first power line; at least part of the first connection wiring line is exposed by the plurality of first connection holes, and at least part of the isolation structure extends into the plurality of first connection holes to electrically connect to the first connection wiring line;
an orthographic projection of the first via on the substrate is staggered with an orthographic projection of the first connection hole on the substrate; and
the isolation structure comprises a recessed portion recessed towards the substrate, an orthographic projection of the recessed portion on the substrate at least partially overlaps with an orthographic projection of the first via on the substrate.

13. The display panel according to claim 1, further comprising a first insulating layer and a second insulating layer located between the isolation structure and the wiring layer; a third insulating layer located on the side, facing away from the substrate, of the isolation structure; and a touch-control wiring layer located on a side, facing away from the substrate, of the third insulating layer;
wherein the first insulating layer comprises a first via, the second insulating layer comprises a second via, and the third insulating layer comprises a third via, an orthographic projection of the second via on the substrate is located within an orthographic projection of the first via on the substrate, the first via, the second via, and the third via are in communication to expose at least part of the first power line, an orthographic projection of the isolation structure on the substrate is staggered with orthographic projections of the first via, the second via, and the third via on the substrate; and
the plurality of first connection holes extend through the third insulating layer, the touch-control wiring layer comprises a touch-control wiring line and a second connection wiring line in the same layer, the second connection wiring line partially extends into the first via, the second via and the third via to electrically connect to the first power line, part of the second connection wiring line is electrically connected to the isolation structure through the plurality of first connection holes.

14. The display panel according to claim 1, wherein the isolation structure comprises a supporting portion, and a shielding portion located on a side, facing away from the substrate, of the supporting portion, and an orthographic projection of the supporting portion on the substrate is located within an orthographic projection of the shielding portion on the substrate;
under a same etching condition, an etch resistance of the supporting portion is weaker than an etch resistance of the shielding portion;
a material of the supporting portion comprises Al, or a material of the shielding portion comprises Ti;
the isolation structure further comprises a transition portion located between the supporting portion and the substrate;
an orthographic projection of the transition portion on the substrate is located within the orthographic projection of the shielding portion on the substrate; and
a material of the transition portion comprises Mo.

15. A display panel, provided with a display region and a bonding region located beside the display region, comprising:
a substrate;
a wiring layer located on a side of the substrate; and
an isolation structure located on a side, facing away from the substrate, of the wiring layer;
wherein the wiring layer comprises at least one first power line, and a first end of the first power line overlaps with the bonding region; at least part of the isolation structure is located in the display region and electrically connected to the bonding region through the at least one first power line; the isolation structure comprises at least one connection region, an orthographic projection of the connection region on the substrate is located within an orthographic projection of the first power line on the substrate, the isolation structure is connected to the first power line in the connection region, and a total area of the at least one connection region is greater than or equal to 0.1% of an area of the display region.

16. The display panel according to claim 15, wherein the display region and the bonding region are arranged along a first direction, the first power line extends from the bonding region along the first direction to connect to the isolation structure;
a sum of widths of the at least one connection region along a second direction is greater than or equal to 1/20 of a length of the display region in a second direction, and the first direction intersects with the second direction.

17. The display panel according to claim 16, wherein the connection region comprises a plurality of first connection holes, and the isolation structure is electrically connected to the first power line through the plurality of first connection holes.

18. The display panel according to claim 16, further comprising a first frame region located between the display region and the bonding region, wherein at least three connection regions of the at least one connection region are located within the first frame region and connected to at least three first power lines of the at least one first power line in one-to-one correspondence;
the bonding region comprises at least two sub-bonding regions, and a quantity of the at least one connection region is greater than or equal to a quantity of the sub-bonding regions; and
the sub-bonding region is provided with a driver chip.

19. The display panel according to claim 18, wherein
the display region, the first frame region, and the bonding region are arranged in sequence along the first direction, the at least two sub-bonding regions are arranged along the second direction; and
in the second direction, two connection regions of the at least one connection region are respectively located on two sides of the first frame region, and the at least one first power line is located between two adjacent sub-bonding regions of the at least two sub-bonding regions.

20. A display device, comprising:
a display panel, provided with a display region and a bonding region located beside the display region; the display panel comprising:
a substrate;
a wiring layer located on a side of the substrate; and
an isolation structure located on a side, facing away from the substrate, of the wiring layer;
wherein the wiring layer comprises at least one first power line, and a first end of the first power line is connected to the bonding region; at least part of the isolation structure is located in the display region and electrically connected to the bonding region through the at least one first power line; the isolation structure comprises at least one connection region, an orthographic projection of the connection region on the substrate is located within an orthographic projection of the first power line on the substrate, the connection region comprises a plurality of first connection holes, the isolation structure is electrically connected to a second end of the first power line through the plurality of first connection holes, and a total area of the plurality of first connection holes is greater than a total area of an overlapping region between the first power line and the bonding region.
